(19) United States
(12) Patent Application Publication
(10) Pub. No.: US 2018/0329251 A1
(43) Pub. Date: Nov. 15, 2018

(54) MANUFACTURING METHOD OF DISPLAY SUBSTRATE, DISPLAY SUBSTRATE AND LIQUID CRYSTAL DISPLAY PANEL

(71) Applicant: SHENZHEN CHINA STAR OPTOELECTRONICS TECHNOLOGY CO., LTD., Shenzhen, Guangdong (CN)

(72) Inventor: Xiaoping YU, Shenzhen, Guangdong (CN)

(73) Assignee: Shenzhen China Star Optoelectronics Technology Co., Ltd., Shenzhen, Guangdong (CN)

(21) Appl. No.: 15/543,985

(22) PCT Filed: May 10, 2017
(86) PCT No.: PCT/CN2017/083687

§ 371 Date: Jul. 15, 2017

(30) Foreign Application Priority Data
Apr. 20, 2017 (CN) 201710261634.6

(51) Int. Cl. G02F 1/1343; G03F 7/00; G03F 7/36

(52) U.S. Cl. CPC G02F 1/13439; G03F 7/0002; G02F 1/1368; G03F 7/36; G02F 2202/16; G03F 7/0007

(57) ABSTRACT

The disclosure discloses a manufacturing method of a display substrate, a display substrate and a liquid crystal display panel. The method includes providing a basal substrate, forming a graphene electrode layer with a nanoscale electrode pattern on the basal substrate. According to the method above, the penetration efficiency of light and the electron conduction velocity can be improved, resulting in enhancing the display quality of the display substrate.

### FIELD OF THE DISCLOSURE

The disclosure relates to a display technical field, and more particularly to a manufacturing method of a display substrate, a display substrate and a liquid crystal display panel.

### BACKGROUND

Liquid crystal display devices are widely applied due to numerous advantages such as thin bodies, low power consumption without radiation and so on. The vertical alignment (VA) mode is one of the most commonly used display modes of the conventional liquid crystal display device, which has virtues such as wide visual angles and quick response.

The thin film transistor (TFT) is disposed with the indium tin oxides/slit (ITO/slit) structure, or the color filter (CF) substrate is disposed with the ITO/slit structure simultaneously in the VA mode. The electrical field is distributed aslant between the ITO/slit of the top substrate and that of the bottom substrate by loading voltages to drive liquid crystal molecules. During manufacturing electrodes, the rotary angle of liquid crystal molecules stays 45° by controlling the arrangement of the ITO/slit of the top substrate and that of the bottom substrate to achieve the maximum optical penetration efficiency.

In order to further improve the liquid crystal efficiency, the arrangement of the ITO/slit is gradually minimized. However, as the limitation of the process, the ITO/slit merely can be produced in the micrometer scale, and further miniaturization can hardly be achieved. Meanwhile, other restrictions are brought due to disadvantages such as the relatively high cost of ITO, the low conductivity and poor mechanical stability.

### SUMMARY

The disclosure provides a manufacturing method of a display substrate, a display substrate and a liquid crystal display panel, which can enhance the penetration efficiency of light and electron conduction velocity, and further improve the display quality of the display substrate.

In order to solve the technical problem above, the disclosure provides a display substrate. The display substrate includes a basal substrate. The basal substrate is disposed with a graphene electrode layer with a nanoscale electrode pattern. A first assistance layer with a nanoscale pattern is disposed between the basal substrate and the graphene electrode layer. The nanoscale electrode pattern of the graphene electrode layer is formed by a nanoimprinting technique.

In order to solve the technical problem above, the disclosure further provides a manufacturing method of a display substrate. The method includes providing a basal substrate, forming a graphene electrode layer with a nanoscale electrode pattern on the basal substrate.

In order to solve the technical problem above, the disclosure further provides a liquid crystal display panel. The liquid crystal display panel includes a display substrate. The display substrate includes a basal substrate. The basal substrate is disposed with a graphene electrode layer with a nanoscale electrode pattern.

Beneficial effects of the disclosure is distinguishing from the prior art, the manufacturing method of the display substrate of the disclosure includes providing the basal substrate, and forming the graphene electrode layer with the nanoscale electrode pattern on the basal substrate. As the graphene electrode layer has the nanoscale electrode pattern and the graphene layer is thin and transparent, which can improve the transmissivity of light, and further enhance the display efficiency. And the graphene layer has superior conductivity, which can enhance conduction velocity of electrons, further improving the display quality of the display substrate.

### BRIEF DESCRIPTION OF THE DRAWINGS

FIG. 1 is a schematic flowchart of a manufacturing method of a display substrate according to an embodiment of the disclosure.

FIG. 2 is a structural schematic view of a display substrate according to an embodiment of the disclosure.

FIG. 3 is a schematic flowchart of a manufacturing method of a display substrate according to another embodiment of the disclosure.

FIG. 4 to FIG. 7 are schematic processing views of a manufacturing method of a display substrate according to another embodiment of the disclosure.

FIG. 8 is a schematic flowchart of a manufacturing method of a display substrate according to still another embodiment of the disclosure.

FIG. 9 to FIG. 14 are schematic processing views of a manufacturing method of a display substrate according to still another embodiment of the disclosure.

### DETAILED DESCRIPTION OF PREFERRED EMBODIMENTS

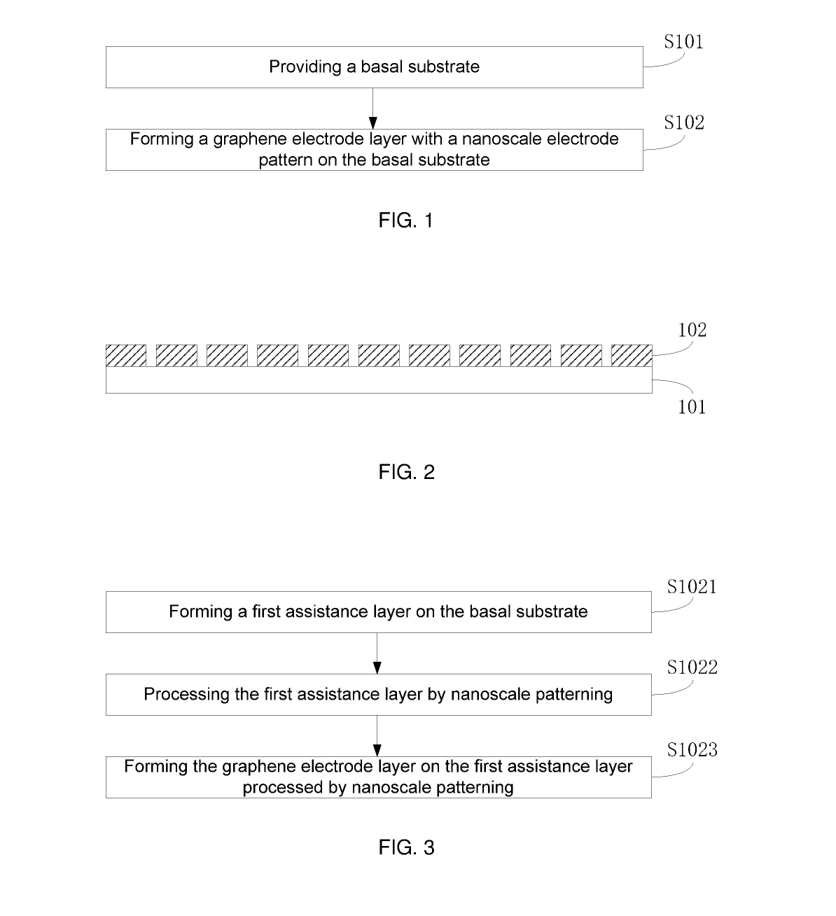

Referring to FIG. 1 and FIG. 2, the manufacturing method of the display substrate of the disclosure includes:

step S101: providing a basal substrate 101.

The basal substrate 101 can be transparent, specifically can be transparent organic materials that can insulate water and oxygen or glass. Various materials can be chosen according to specific sorts of display substrates. A glass substrate and a silicon oxide substrate are common. Polyvinyl chloride (PV), fusible polytetrafluoro ethylene (PFA), polyethylene terephthalate (PET) substrates can also be adopted in some situations. Obviously, the basal substrate 101 can further be a TFT substrate or a CF substrate whose top layer is the previous materials without a formed pixel electrode layer.

Step S102: forming a graphene electrode layer 102 with a nanoscale electrode pattern on the basal substrate 101.

The formation of the nanoscale pattern can be achieved by at least one of photoetching, soft etching, graphene rim printing and the nanoimprinting technique.

Graphene is a novel carbon nanomaterial, which has an extremely high specific surface area, good mechanical strength, extremely high thermal conductivity and optical penetration efficiency, and ultra-superior conductivity and thermal stability. Under the room temperature, the electron mobility of graphene exceeds 15000 cm2/V·s, and the resistivity is merely 10-6Ω·cm, which is a material with the lowest resistivity. Therefore, graphene actually is a transparent conductor. Graphene used as an electrode can guarantee the conduction velocity of electrons and the penetration rate of light, further reducing the consumption of electrode materials and the cost.

The display substrate of the disclosure forms the graphene electrode layer with the nanoscale electrode pattern on the basal substrate 101. As the graphene electrode layer has the nanoscale electrode pattern and the graphene layer is thin and transparent, which can improve the transmissivity of light, and further enhance the display efficiency. And the graphene layer has superior conductivity, which can enhance conduction velocity of electrons, further improving the display quality of the display substrate.

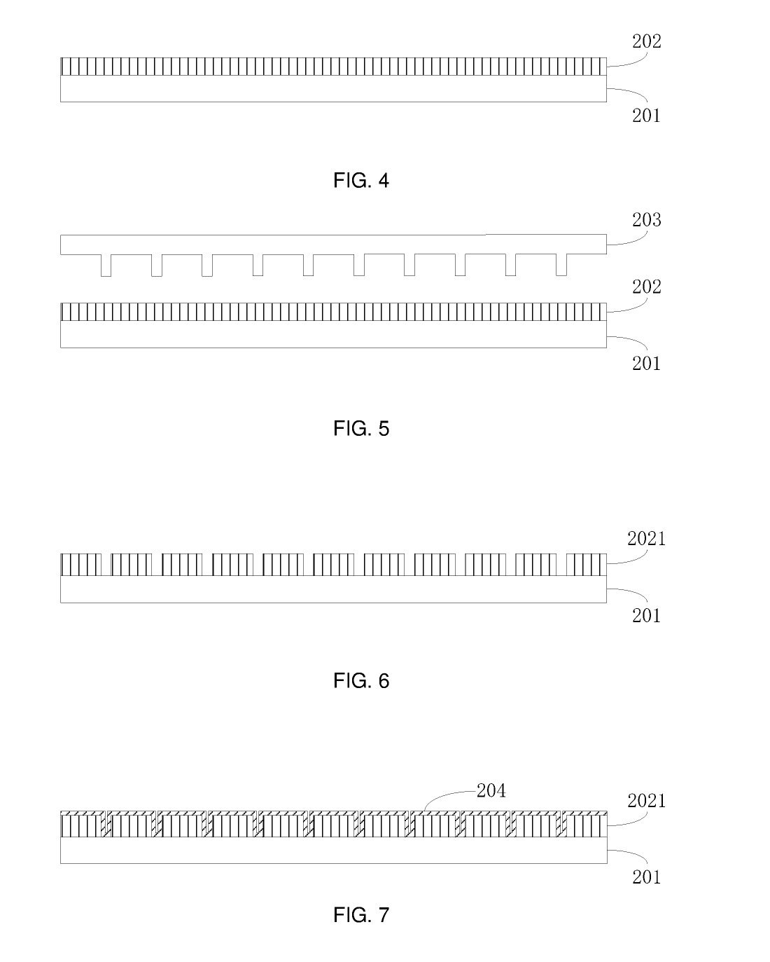

Referring to FIG. 3 to FIG. 7, in an embodiment, step S102 further includes a sub-step S1021, a sub-step S1022 and a sub-step S1023.

Sub-step S1021: forming a first assistance layer 202 on the basal substrate 201.

The first assistance layer 202 can be a transparent layer with a good penetration rate of light, the material of which can specifically be at least one of polymethyl methacrylate (PMMA), polystyrene (PS), polycarbonate (PC), Polyvinyl chloride (PVC) and so on. In a practical situation, the first assistance layer 202 can be processed by nanoimprinting.

The transmittance of PMMA is excellent. PMMA is taken as an example in the embodiment, a specific formation method of the first assistance layer 202 can be coating liquid PMMA on the basal substrate 201 by spin coating, and solidifying the evenly coated liquid to form a PMMA layer. Obviously, other coating methods can be employed as well, such as the spray coating method, the dip coating method, the electro-coating method and the brush method, which will not be limited.

Sub-step S1022, processing the first assistance layer 202 by nanoscale patterning.

Processing the first assistance layer 202 by nanoscale patterning can adopt photoetching, electron-beam direct-write, X-rays exposure, ultra-deep ultraviolet light source exposure, the vacuum ultraviolet photoetching technology, soft etching and the nanoimprinting technique.

In the embodiment, the nanoimprinting technique is specifically adopted to process the first assistance layer 202 by nanoscale printing. The adoption of the nanoimprinting technique can form a three-dimensionally artificial structure with a large area whose image resolution is less than 10 nm on the PMMA layer to achieve the nanoscale patterning process thereof. The nanoimprinting technique has exceedingly high image resolution without diffraction in optical exposure or diffraction in electron beam exposure, but can be parallel processed as the optical exposure. Hundreds of thousands of devices can be produced simultaneously, which have the virtue of high yield. Meanwhile, the nanoimprinting technique has no requirement on a complex optical system like an optical exposure equipment, or a complex electromagnetic focusing system like an electron beam exposure equipment, resulting in a low cost. The pattern on the mask can be almost nondestructively transferred to a wafer, which has a high fidelity.

The nanoimprinting technique includes a thermal imprint photoetching technique, a UV solidified nanoimprinting technique, a micro contact nanoimprinting technique, a soft imprinting technique and so on. The first assistance layer 202 is specifically processed for nanoscale patterning by the thermal imprint photoetching technique in the embodiment.

An imprinting mold 203 adopted in the process of nanoscale patterning can be SiC, Si₃N₄, SiO₂, etc. with high accuracy, hardness and stable chemical properties. The imprinting mold 203 can form the required nanoscale pattern by the electron beam etching technique or the reactive ion etching technique.

PMMA is taken as an example, the process of thermally imprinting the first assistance layer 202 to form the nanoscale pattern can specifically be heating the PMMA layer till the temperature exceeds the glass-transition temperature thereof. The heating manner can specifically be heating by a heating board, heating by ultrasonic waves, etc. The adoption of heating by ultrasonic waves can reduce the heating process to several seconds, which is benefit for cutting the power consumption, enhancing the yield and reducing costs. After heating, the imprinting mold is pressed. The heating temperature and the pressure last for a while to fill nanoscale pattern gaps of the mold 203 with the liquid PMMA. The PMMA layer completes the process of nanoscale patterning by removing the mold after the temperature is below the glass-transition temperature.

In a practical situation, in order to reduce the influence of air bubbles on the quality of transferred pattern, the whole process is performed in vacuum that is lower than 1 Pa. The vacuum condition can exhaust gases in the first assistance layer 202 to reduce the influence of the bubbles on the pattern quality during imprinting, and further improving the quality of the formed nanoscale pattern.

In a practical situation, a gas assisted nanoimprinting technique can be adopted, which specifically is aligning the mold 203 and the basal substrate 201 with the first assistance layer 202 before imprinting and fixing them in a vacuum cavity, then filling inert gases in the vacuum cavity for increasing the pressure. The pressure is even and the pressure can be controlled by air input in the manner, which can prevent the problem of the holder being adaptively adjusted in multiple degrees of freedom during the mechanically pressing process, resulting in simplifying the process.

Sub-step S1023: forming a graphene electrode layer 204 on a first assistance layer 2021 processed by nanoscale patterning.

Forming the graphene electrode layer 204 on the first assistance layer 2021 processed by nanoscale patterning is specifically processed by forming a graphene thin film layer thereon.

The graphene thin film can have 1˜10 layers of monatomic graphene. The graphene thin film can specifically be formed by at least one of chemical vapor deposition, the oxidation-reduction method, the mechanical peeling method, the carbon nanotube cracking method and SiC extension growing method.

Furthermore, after forming the graphene electrode layer 204, processes such as polyimide (PI) coating, one drop filling (ODF), etc. will be continuously performed to produce the display device. And external voltage is loaded to drive the liquid crystal to redirection so as to achieve the function of liquid crystal display.

According to the embodiment, the adoption of the thermal imprinting technique can form the nanoscale pattern with high quality and low costs. And the employment of the graphene electrode layer 204 with the nanoscale electrode pattern can improve the display quality of the display substrate.

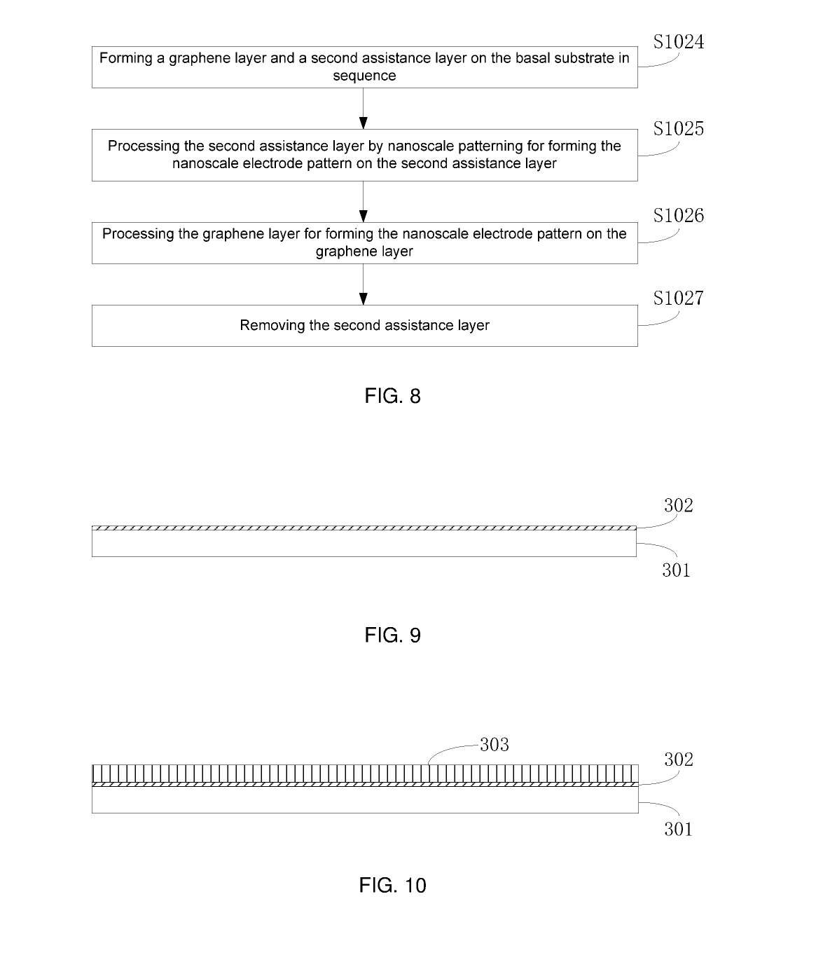

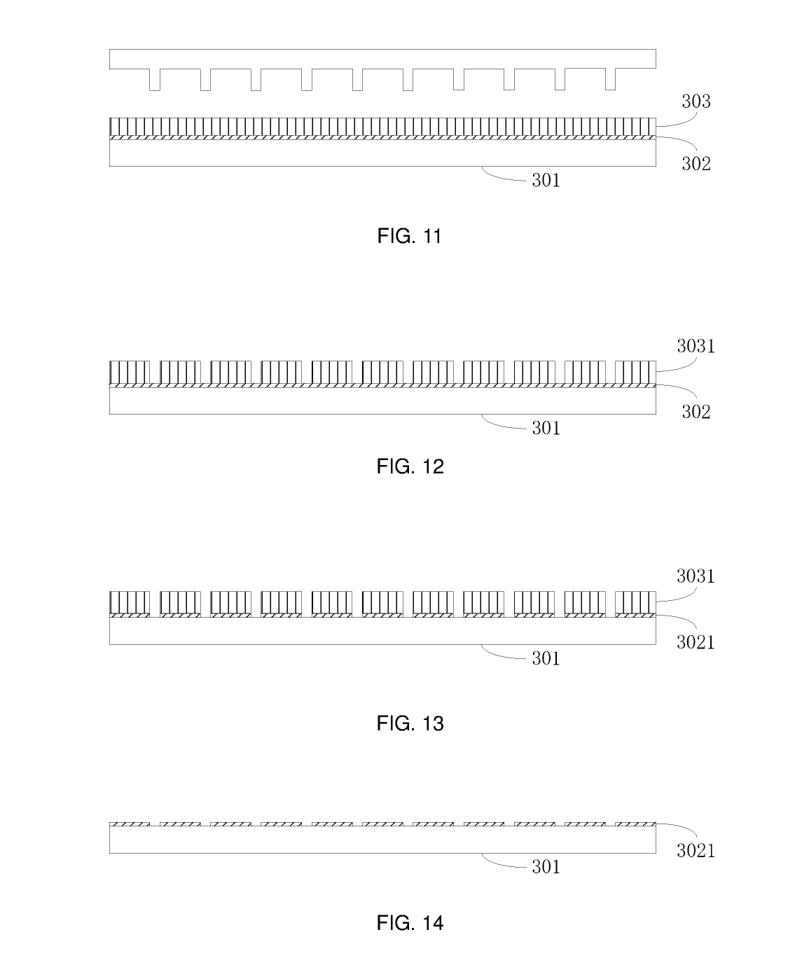

Referring to FIG. 8 to FIG. 14, in an embodiment, step S102 includes a sub-step S1024, a sub-step S1025, a sub-step S1026 and a sub-step S1027.

Sub-step S1024: forming a graphene layer 302 and a second assistance layer 303 on the basal substrate 301 in sequence.

Sub-step S1025: processing the second assistance layer 303 by nanoscale patterning for forming the nanoscale electrode pattern on the second assistance layer.

The formation manner of the graphene layer 302 in the embodiment is basically identical to the relative content in the embodiment above. Meanwhile, the material of the second assistance layer 303 and the formation manner are almost the same with the relative content of the first assistance layer in the previous embodiment, which can be referred to the embodiments above and will not be repeated.

Sub-step S1026: processing the graphene layer 302 for forming the nanoscale electrode pattern on the graphene layer 302.

The graphene layer 302 can be processed by a plasma surface treatment technology, photoetching, laser etching, etc. RIE is specifically used in the embodiment to form a pattern identical to that of the second assistance layer 3031 with the nanoscale pattern on the graphene layer 302.

Sub-step S1027: removing the second assistance layer 3031 with the nanoscale pattern.

In the embodiment, the second assistance layer 3031 with the nanoscale pattern can be removed after forming the nanoscale electrode pattern on the graphene layer 302.

The removal of the second assistance layer 3031 with the nanoscale pattern can specifically be achieved by immersion in the soluble organic solution. PMMA is again used as an example, at least one of acetone, dimethylformaid (DMF), dichloromethane, chlorobenzene, methylbenzene, tetrahydrofuran, chloroform, etc. can be utilized. The alkaline solution can be used as well, such as the NaOH solution. Obviously, methods of heating and ultrasound can further be adopted as an assistant to accelerate the removal of the PMMA layer.

Furthermore, after forming the graphene electrode layer 204, processes such as polyimide (PI) coating, one drop filling (ODF), etc. will be continuously performed to produce the display device. And external voltage is loaded to drive the liquid crystal to redirection so as to achieve the function of liquid crystal display.

The graphene electrode layer 3021 with the nanoscale electrode pattern is finally formed on the substrate according to the embodiment. Besides the beneficial effects of the embodiments above, as the removal of the PMMA layer can prevent the influence of the interference caused by the PMMA layer and the basal substrate on the display efficiency, the optical penetration rate of the display substrate is further enhanced, and the display substrate is made to be thinner and lighter.

In an embodiment related to the thin film transistor substrate of the disclosure, the thin film transistor substrate is specifically produced according to any one of the manufacturing methods of the display substrate described above. The specific methods are as description in the embodiments above, which will not be repeated. The thin film transistor substrate in the embodiment adopts the graphene electrode layer with the nanoscale electrode pattern. And the graphene layer is thin and transparent, which can enhance the penetration rate of light, and further improving the display efficiency. And the graphene layer has good conductivity, which can increase the conduction velocity of electrons, and further improving the display quality of the display substrate.

In an embodiment related to the color filter substrate of the disclosure, the color filter substrate is specifically produced according to any one of the manufacturing methods of the display substrate described above. The specific methods are as description in the embodiments above, which will not be repeated. The color filter substrate in the embodiment adopts the graphene electrode layer with the nanoscale electrode pattern. And the graphene layer is thin and transparent, which can enhance the penetration rate of light, and further improving the display efficiency. And the graphene layer has good conductivity, which can increase the conduction velocity of electrons, and further improving the display quality of the display substrate.

In an embodiment related to the liquid crystal display panel of the disclosure, the liquid crystal display panel includes the substrates in the embodiment related to the thin film transistor substrate and/or the embodiment related to the color filter substrate. The liquid crystal display panels of the disclosure include the liquid crystal display panel used in electrical devices such as televisions displayed via the liquid crystal, computers, tablets, mobile phones, MP3, MP4, etc., especially indicate VA sorts such as MVA and PVA of liquid crystal display panels. The liquid crystal display panel in the embodiment is highly efficient with extremely superior display quality.

The description above is merely embodiments of the disclosure, which cannot limit the protection scope of the disclosure. Any equivalent structure or process according to contents of the disclosure and the figures, or direct or indirect application in other related fields should be included in the protected scope of the disclosure.

What is claimed is:

1. A display substrate, the display substrate comprising a basal substrate;
the basal substrate disposed with a graphene electrode layer with a nanoscale electrode pattern;
a first assistance layer with a nanoscale pattern disposed between the basal substrate and the graphene electrode layer;
the nanoscale electrode pattern of the graphene electrode layer formed by a nanoimprinting technique.

2. The display substrate according to claim 1, wherein a material of the first assistance layer is polymethyl methacrylate.

3. The display substrate according to claim 1, wherein the nanoimprinting technique is a thermal imprint photoetching technique.

4. A manufacturing method of a display substrate, the method comprising:
providing a basal substrate;
forming a graphene electrode layer with a nanoscale electrode pattern on the basal substrate.

5. The method according to claim 4, wherein forming the graphene electrode layer with the nanoscale electrode pattern on the basal substrate comprises:
forming a first assistance layer on the basal substrate;
processing the first assistance layer by nanoscale patterning;
forming the graphene electrode layer on the first assistance layer processed by nanoscale patterning.

6. The method according to claim 4, wherein forming the graphene electrode layer with the nanoscale electrode pattern on the basal substrate comprises:
forming a graphene layer and a second assistance layer on the basal substrate in sequence;
processing the second assistance layer by nanoscale patterning for forming the nanoscale electrode pattern on the second assistance layer;
processing the graphene layer for forming the nanoscale electrode pattern on the graphene layer;
removing the second assistance layer.

7. The method according to claim 4, wherein forming the graphene electrode layer with the nanoscale electrode pattern on the basal substrate comprises:
forming the graphene electrode layer with the nanoscale electrode pattern on the basal substrate by a nanoimprinting technique.

8. The method according to claim 7, wherein the nanoimprinting technique is a thermal imprint photoetching technique.

9. The method according to claim 5, wherein a material of the first assistance layer is polymethyl methacrylate.

10. The method according to claim 6, wherein a material of the second assistance layer is polymethyl methacrylate.

11. The method according to claim 6, wherein processing the graphene layer for forming the nanoscale electrode pattern on the graphene layer comprises:
processing the graphene layer by a plasma surface treatment technology for forming the nanoscale electrode pattern on the graphene layer.

12. A liquid crystal display panel, the liquid crystal display panel comprising a display substrate;
the display substrate comprising a basal substrate;
the basal substrate disposed with a graphene electrode layer with a nanoscale electrode pattern.

13. The liquid crystal display panel according to claim 12, wherein a first assistance layer with a nanoscale pattern is disposed between the basal substrate and the graphene electrode layer.

14. The liquid crystal display panel according to claim 13, wherein a material of the first assistance layer is polymethyl methacrylate.

15. The liquid crystal display panel according to claim 12, wherein the nanoscale electrode pattern of the graphene electrode layer is formed by a nanoimprinting technique.

16. The liquid crystal display panel according to claim 15, wherein the nanoimprinting technique is a thermal imprint photoetching technique.
